(19) United States
(12) Patent Application Publication
(10) Pub. No.: US 2014/0166087 A1
(43) Pub. Date: Jun. 19, 2014

(54) SOLAR CELLS HAVING GRADED DOPED REGIONS AND METHODS OF MAKING SOLAR CELLS HAVING GRADED DOPED REGIONS

(71) Applicant: INTEVAC, INC., Santa Clara, CA (US)

(72) Inventors: Henry Hieslmair, Sunnyvale, CA (US); Babak Adibi, Los Altos, CA (US)

(73) Assignee: INTEVAC, INC., Santa Clara, CA (US)

(21) Appl. No.: 13/719,145

(22) Filed: Dec. 18, 2012

(51) Int. Cl. H01L 31/0352; H01L 31/18

(52) U.S. Cl. CPC H01L 31/03529; H01L 31/18
USPC 136/255; 438/87

(57) ABSTRACT

A photovoltaic cell having a graded doped region such as a graded emitter and methods of making photovoltaic cells having graded doped regions such as a graded emitter are disclosed. Doping is adjusted across a surface to minimize resistive (I2R) power losses. The graded emitters provide a gradual change in sheet resistance over the entire distance between the lines. The graded emitter profile may have a lower sheet resistance near the metal lines and a higher sheet resistance farther from the metal line edges. The sheet resistance is graded such that the sheet resistance is lower where I2R power losses are highest due to current crowding. One advantage of graded emitters over selective emitters is improved efficiency. An additional advantage of graded emitters over selective emitters is improved ease of aligning metallization to the low sheet resistance regions.

### BACKGROUND

1. Field

This invention relates to the art of methods for making solar cells and, more particularly, to solar cells having graded doped regions and methods of making solar cells with graded doped regions. Doped regions can include emitters and surface fields.

2. Related Art

Solar cells, also known as photovoltaic (PV) cells, convert solar radiation into electrical energy. Solar cells are fabricated using semiconductor processing techniques, which typically, include, for example, deposition, doping and etching of various materials and layers. Typical solar cells are made on semiconductor wafers or substrates, which are doped to form p-n junctions in the wafers or substrates. Solar radiation (e.g., photons) directed at the surface of the substrate cause electron-hole pairs in the substrate to be broken, resulting in migration of electrons from the n-doped region to the p-doped region (i.e., an electrical current is generated). This creates a voltage differential between two opposing surfaces of the substrate. Metal contacts, coupled to electrical circuitry, collect the electrical energy generated in the substrate. FIG. 1 illustrates an exemplary solar cell.

Within the solar cell, the photo generated current flows to the metal contact regions. The metal contacted regions can be lines or spots or other specialized shapes. In a typical front contacted solar cell, the front fingers are the lines. Current flows through the emitter to reach the current collecting lines, as shown in FIG. 2. In FIG. 2, the metal lines are 2 mm apart with the midpoint at 1 mm. In industry, the pitch of the metal lines is typically between 1 and 3 mm.

In advanced cell structures such as Laser Fired Back Contact or PERL cells, the metal contact is a point or spot contact. In an emitter wrap through or metal wrap through, the via holes are similar to point contacts. In the Sunpower solar cell design, the rear contact is formed with rows of closely spaced spots. Other unique shapes can be used, including, for example, stars and snowflake patterns.

As current from regions of the cell converge on the metal contact regions, “current crowding” can occur. The current in the emitter increases approximately linearly from midpoint between two fingers approaching the fingers, as shown in FIG. 3.

The resistive power loss increases as the square of the current in the emitter. A computer simulation (PC2D) for the current in a 60Ω/□ emitter is shown in FIG. 3. The I2R power loss for the same emitter is shown in FIG. 4. Also shown in FIG. 4 is the carrier recombination loss in the emitter by the open circles. In this simulation, the cell efficiency is 17.8%. Since the power loss is P=I2R, the increase in current near the metal contact increases the resistance power loss as the square of the current.

One simple method to reduce this resistive power loss is to lower the sheet resistance of the emitter. However, doing so increases the recombination and optical losses in the emitter. Thus higher sheet resistances are desired for improved voltage and current. The metal line is typically formed using a silver based paste. Such metallizations require lower sheet resistances to make good electrical contacts to the silicon.

| | Low sheet | High sheet |
|---|---|---|
| | resistance | resistance |
| Resistive I²R losses | decrease | increase |
| Silicon to metal contact resistance | decrease | increase |
| Recombination losses Voc | increase | decrease |
| Light absorption losses Jsc | increase | decrease |

To summarize, low sheet resistances (high doping) improve I²R power losses as well as form good contacts to the metallization. Unfortunately, low sheet resistances increase recombination losses, reducing V_{oc}, and optical losses, reducing J_{sc}. Much work has been done to optimize these competing constraints. One approach is called selective emitter. Selective emitters have a lower sheet resistance under the metal fingers to address contact resistance issues between the emitter and the silver paste.

FIG. 5 illustrates the sheet resistance and power losses in a selective emitter cell in which the sheet resistance under the metal finger is 60Ω/□, and the sheet resistance away from the metal finger is 90Ω/□. Selective emitters have a uniform sheet resistance between the metal fingers, and, therefore exhibit higher I²R power losses which counter diminish the benefits of lower recombination losses in the high sheet resistance regions. The simulation cell efficiency is 18.4% which is an improvement from the earlier 60Ω/□ emitter.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

According to an aspect of the invention, a photovoltaic cell is provided that includes a substrate comprising a graded doping region; and a plurality of metal contacts in contact with at least a portion of the graded doping region.

The substrate may include silicon. The photovoltaic cell may further include a plurality of busbars in contact with the plurality of metal contacts.

The graded doping region may include a graded emitter. The graded doping region may include a gradient of dopant in the substrate. The graded doping region may include a gradual change in sheet resistance over the distance between two of the adjacent plurality of metal contacts. An amount of dopant of the graded doping region may be higher at a region of the substrate that experiences current crowding. An amount of dopant of the graded doping region may be selected so that there is a gradual change in sheet resistance from one of the plurality of the metal contacts to an adjacent one of the plurality of the metal contacts. A dopant profile of the graded doping region may be selected so that a sheet resistance of the substrate near each of the plurality of metal contacts is lower than a sheet resistance of the substrate at a midpoint between each of the plurality of metal contacts. The graded doping region may include a gradient and a plateau of sheet resistance.

According to another aspect of the invention, a method of making a photovoltaic cell is provided that includes forming a graded doping region in a substrate; and forming a plurality of metal contacts over the substrate.

Forming the graded doping region may include doping the substrate. The doping may include ion implantation. The doping may include plasma immersion doping. The doping may include plasma grid implantation.

The doping may include ion implanting a dopant in a gradient profile in a substrate; and activating the dopant.

The dopant may be ion implanted in a gradient profile between the metal contacts. The gradient profile may be configured to provide a low sheet resistance near the metal lines and a high sheet resistance between the metal lines.

According to a further aspect of the invention, a method of making a photovoltaic cell is provided that includes ion implanting a dopant in a substrate to form a plurality of graded doping regions; forming a plurality of metal lines on the substrate, wherein the graded doping region comprises a gradient profile formed between adjacent lines of the plurality of metal lines.

The implanting may include ion implantation. The implanting may include plasma immersion doping. The implanting may include plasma grid implantation.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1 illustrates a photovoltaic cell.

FIG. 2 illustrates current flow in a prior art photovoltaic cell.

FIG. 3 is a chart illustrating current crowding at the metal contact regions in prior art photovoltaic cells.

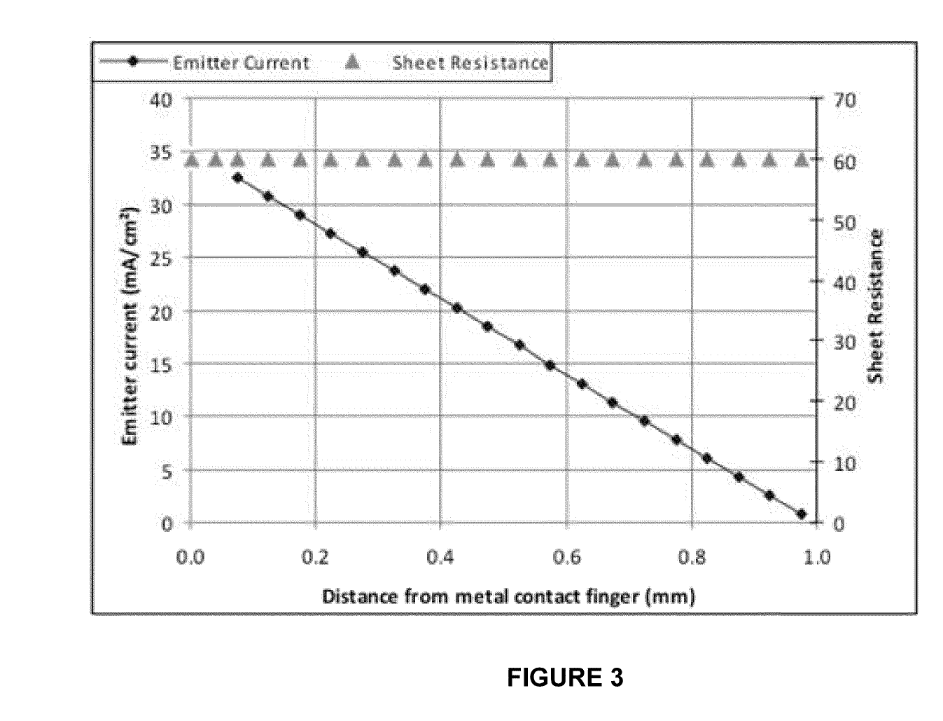

FIG. 4 is a chart illustrating that resistive power loss increases as the square of the current in the emitter in prior art photovoltaic cells.

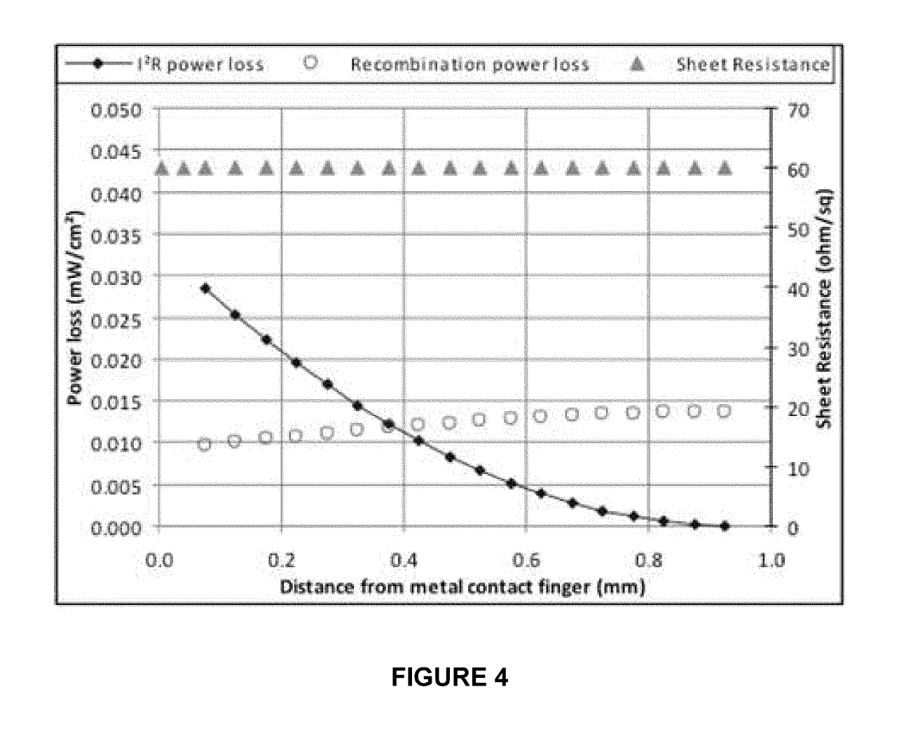

FIG. 5 is a chart illustrating sheet resistance and power losses in a selective emitter of prior art photovoltaic cells.

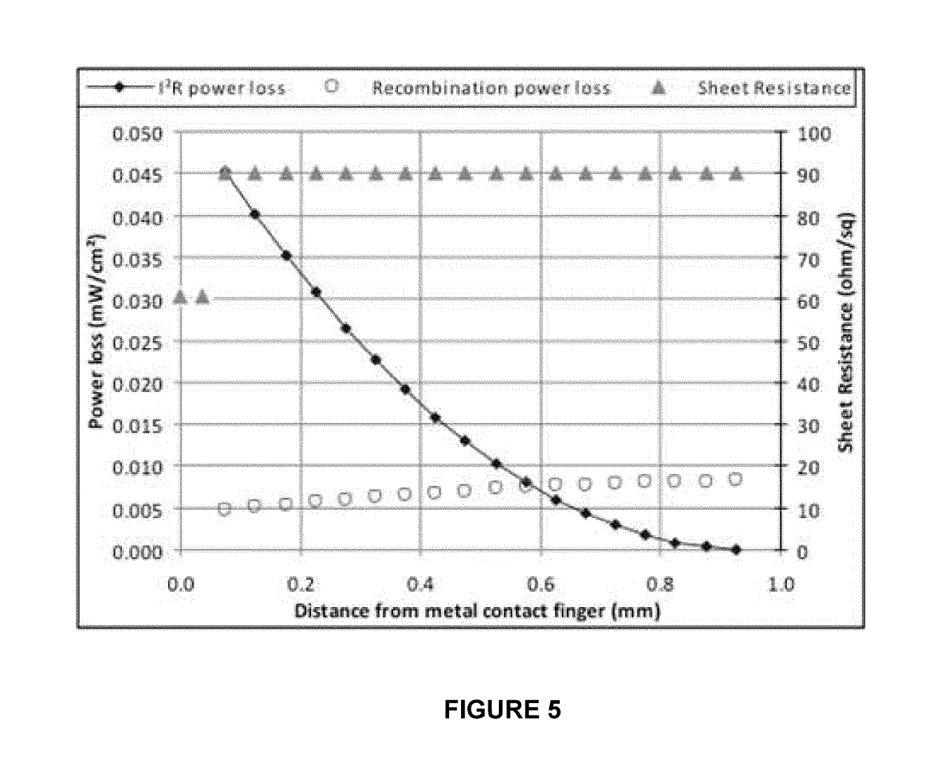

FIG. 6 is a chart illustrating a graded emitter according to one embodiment of the invention.

FIG. 7 is a chart illustrating a graded emitter according to one embodiment of the invention, in comparison with a selective emitter of the prior art.

FIG. 8 is a chart illustrating a doping profile of a graded emitter according to one embodiment of the invention.

FIG. 9 is a flow diagram showing a method of making a photovoltaic cell according to one embodiment of the invention.

FIG. 10 illustrates an exemplary shadow mask for forming a graded emitter having the doping profile shown in FIG. 8 according to one embodiment of the invention.

FIG. 11 is a flow diagram showing a method of making a photovoltaic cell according to one embodiment of the invention.

FIG. 12 is a graph comparing a graded emitter according to one embodiment of the invention to a selective emitter.

### DETAILED DESCRIPTION

Embodiments of the invention are directed to photovoltaic (solar) cells having graded doping regions, such as graded emitters. Since the power loss is not uniform across the graded doping region, a more optimal solution to reduce the power loss described above is to decrease the sheet resistance in the regions of highest current.

Graded doping lowers the sheet resistance in the regions of highest current in proportion to the I²R losses. Graded doping can be used in any region that collects current and/or experiences current crowding. Embodiments of the invention are also directed to graded back surface fields or graded doping for base contacts. Graded emitters or other graded doping regions are formed by grading the dopant concentration. Sheet resistance is generally proportional to doping concentration. The dopant profile of the graded doping region can be selected so that there is a lower sheet resistance near the metal contacts and a higher sheet resistance at a further distance from the metal contacts. In some embodiments, the dopant profile results in a gradual change in sheet resistance from one metal contact to another, adjacent metal contact. In some embodiments, the dopant profile results in a plateau of sheet resistance at the metal contacts and/or at a distance mid-way between the metal contacts, but with a gradual change in the dopant profile near the metal contacts.

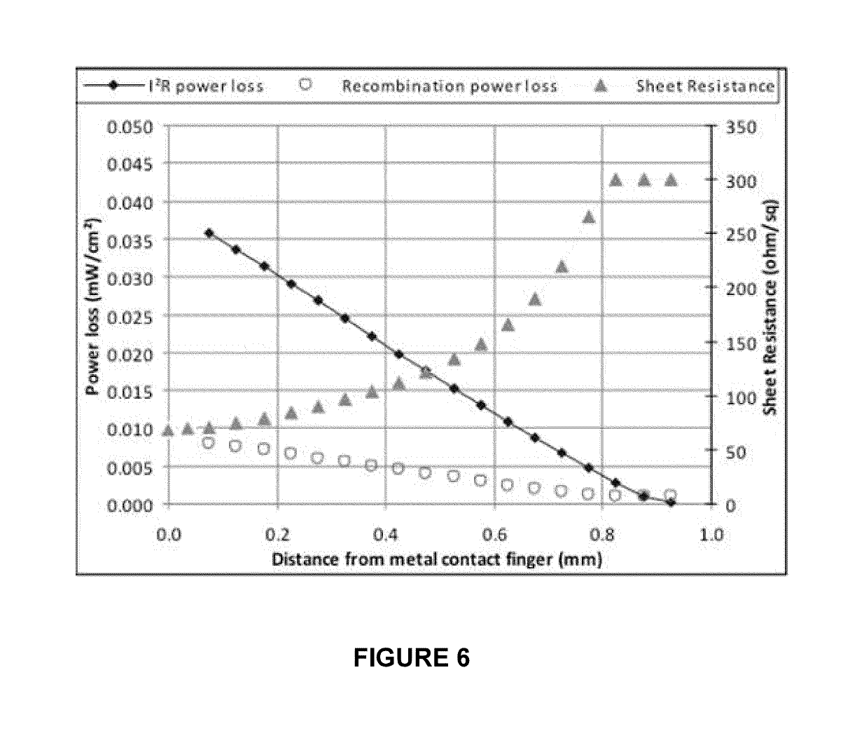

FIG. 6 is an example of a graded emitter of the invention with lower sheet resistance near the metal collector for reduced I²R losses and higher sheet resistance near the mid point between two metal contacts. The predicted cell efficiency for the graded emitter is 18.5%, a slight improvement over the selective emitter.

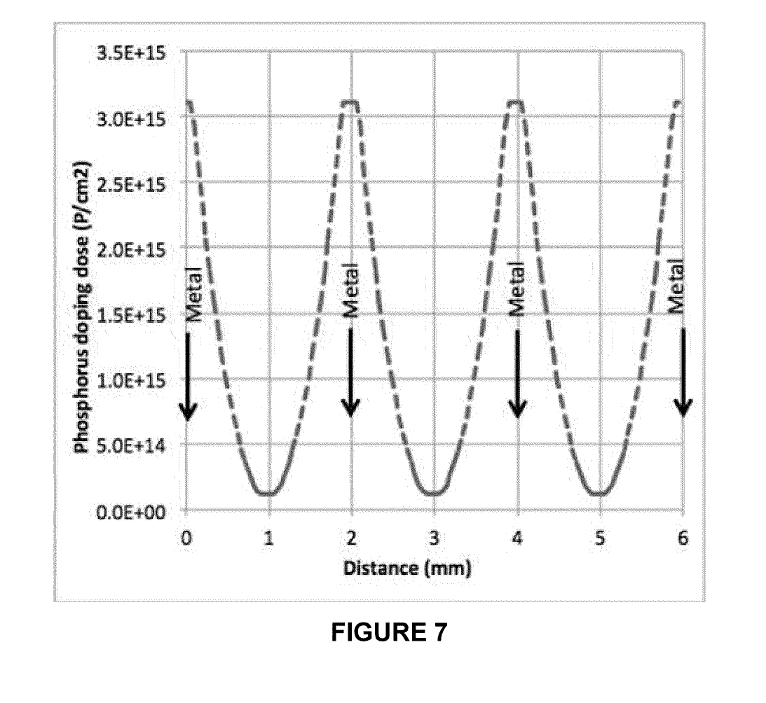

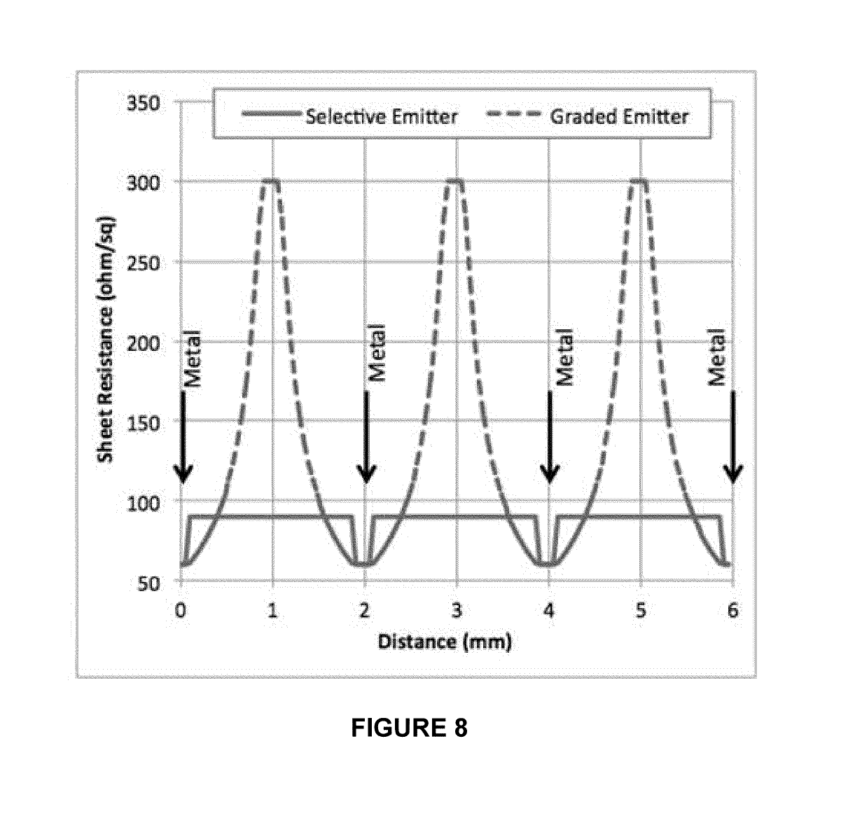

The doping pattern corresponding to the graded emitter in FIG. 6 is shown in FIG. 7 for four fingers. An illustration comparing the sheet resistance of the selective and graded emitters is shown in FIG. 8. In FIG. 8, four metal fingers and the sheet resistance of the emitter between each of the metal fingers is shown. In both cases, the sheet resistance below the metal is lower to improve the contact resistance to the metal. In FIG. 8, the sheet resistance under the metal is 60Ω/□. It will be appreciated that different pastes can be selected or used to generate higher sheet resistances. In the case of the selective emitter, the width of the 60Ω/□ sheet resistance line that the metal must align with is less than 200 microns, which is a difficult target to align to. In contrast, the graded emitter of the invention has 500 micron or more width for the metal line to align with, due to the less abrupt sheet resistance changes.

The thin fingers can be screen printed with a fire-through-paste which etch through the top cell passivating layer to contact the silicon. Bus bars which are perpendicular to the fingers cross through the high sheet resistance zones of the graded doping. If the busbars are formed in the same screen print with the same fire-through paste, the busbar metal may shunt the solar cell. Thus, busbars can be printed separately with a non-fire-through paste to avoid contacting the silicon in the high sheet resistance zones.

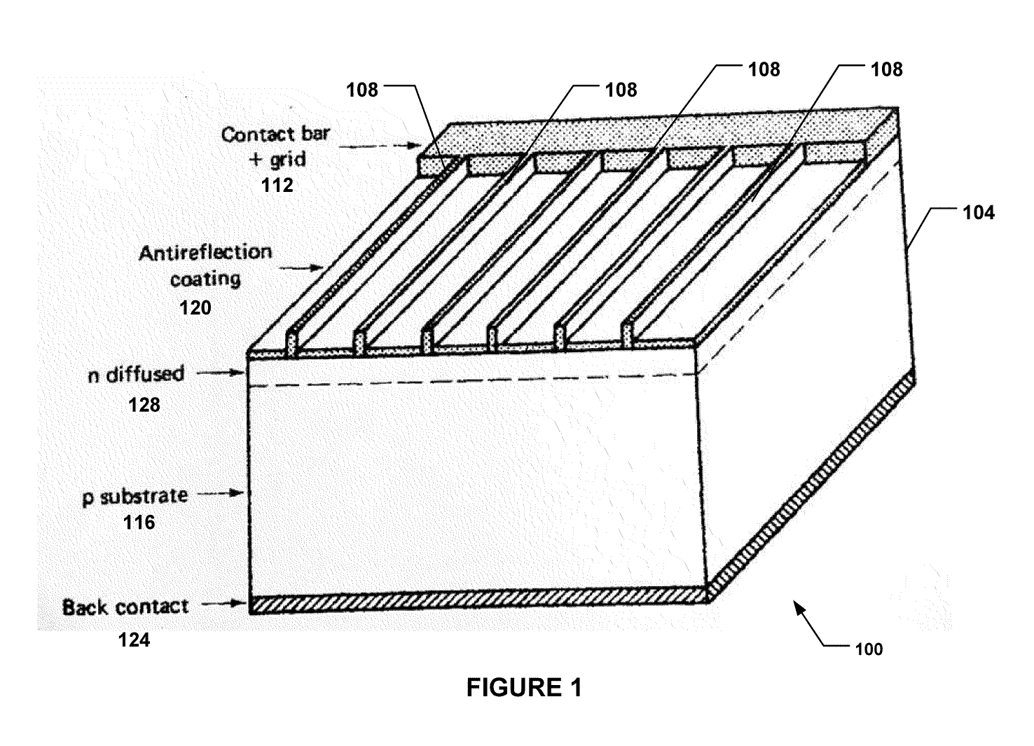

With reference back to FIG. 1, a photovoltaic cell 100 according to an embodiment of the invention is shown. The photovoltaic cell 100 includes a base 104, multiple lines 108 and a bus bar 112. It will be appreciated that the photovoltaic cell may include fewer or more lines 108 than shown in FIG. 1, and that the photovoltaic cell may include more than one bus bar 112 as shown in FIG. 1. The base 104 includes a substrate 116 and a passivation layer 120 formed over the substrate 116. The lines 108 are formed in the passivation layer 120. The bus bar 112 is formed over the lines 108 and the passivation layer 120. A contact 124 is formed on the side of the substrate opposite the lines 108 and bus bar 112.

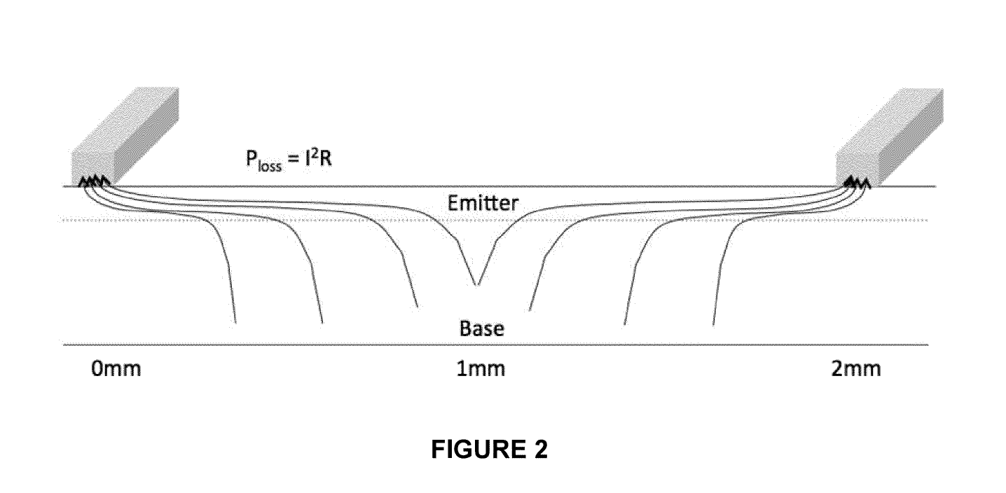

The lines 108 are linear contacts on the front surface of the cell. The lines 108 are metal fingers that are typically about 100 μm wide are positioned every 1.5 to 2.5 mm across the surface of the cell. The lines 108 collect current that is generated in the regions between the lines. It will be appreciated that although the photovoltaic cell 100 is depicted with metal lines 108 (i.e., linear contacts) in FIGS. 1 and 2, other shapes can be used for the contacts, as known to those of skill in the art, including, for example, points, dots, circles, stars, snowflakes, and the like.

Graded doping regions 128 are formed in the substrate 104. In one embodiment, the graded doping regions 128 are graded emitters. The graded doping regions 128 provide a gradual change in sheet resistance over the entire distance between the lines 108. In some embodiments, the profile of the graded doping region has a lower sheet resistance near the metal lines with a higher sheet resistance farther from the metal line edges (e.g., at the mid-point between the lines 108).

The graded doping regions 128 are formed by doping the substrate 104. Any known dopant may be used, including, for example, boron, phosphorous, arsenic, antimony, and the like. In one embodiment the concentration of these implants is less than 1E15 cm⁻². FIG. 8 illustrates an exemplary doping profile for the graded emitters 128 of the invention. It will be appreciated that the doping profile may vary from that shown in FIG. 7.

A comparison between an exemplary graded emitter and a typical prior art selective emitter is shown in FIG. 8. In this example, the metal lines or fingers are positioned every 2 mm, starting at 0 mm. In cells having a graded emitter, there is a gradual change in sheet resistance over the distance between the fingers. In contrast, the selective emitter has a square wave in sheet resistance over the distance between the fingers. In some embodiments, the graded emitter may have a plateau of sheet resistance at the high sheet resistances. This plateau is distinguishable from the square wave selective emitter because of the gradual change near the metal fingers.

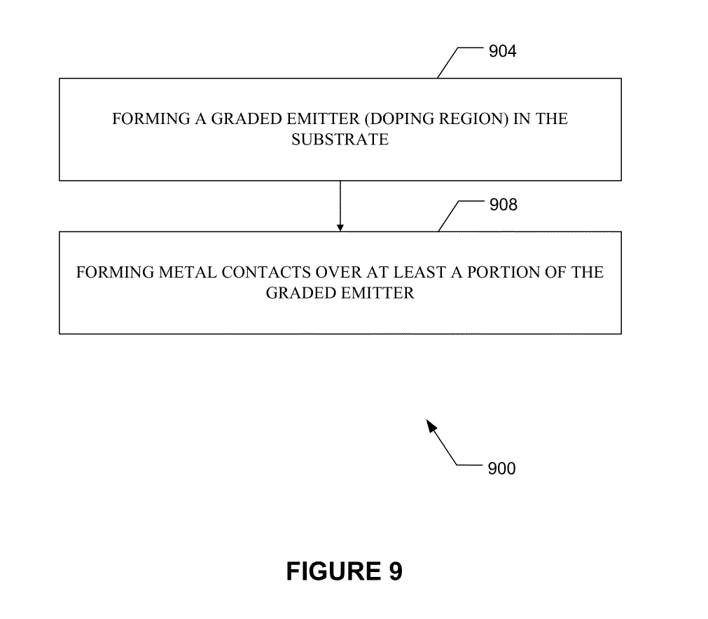

FIG. 9 illustrates a method of making a photovoltaic cell having a graded emitter according to some embodiments of the invention. As shown in FIG. 9, the method 600 includes forming a graded emitter (graded doping region) in the substrate (block 904), and forming metal contacts over at least a portion of the graded emitter (graded doping region) (block 908).

In some embodiments, the graded doping region is formed using graded doping by ion implantation. There are a number of ion implantation tools that may be used according to embodiments of the invention.

An exemplary implanter that may be used to form the graded emitter is a spot beam. The spot beam may be any size or range of sizes between a few millimeters and a few centimeters in diameter. The spot beam is rastered across the entire surface of the substrate. The raster pattern is typically optimized to produce a uniform doping density across the whole surface of the implanted piece. However, the raster pattern can be modified to form graded doping features selectively on the substrate.

Another exemplary implanter may have a long and thin rectangular beam that can also be rastered substrate. If the spot is thin enough, then either the beam or wafer sweep speed or the beam current (or both) can be modulated to form graded doping features selectively on the substrate.

Another exemplary implanter is a broad beam implanter. Broad beam implanters are advantageous because they offer very high productivity. Plasma immersion implantation is a common broad beam implanting method. In plasma immersion implantation, the substrate is biased to attract the prevalent doping ions to the substrate. The implantation in these systems is non-conformal because the system typically has very limited ion optics elements available and thus cannot be manipulated ion optically. Nevertheless, graded doping can be implemented using shadow masks that provide distinct doping regions on the substrate. Broad beam implantation with a shadow mask to provide distinct doping regions is disclosed in commonly assigned U.S. patent application Ser. No. 13/024,251, Feb. 9, 2011, the entirety of which is hereby incorporated by reference.

In some embodiments, antennas are positioned underneath the wafer to provide selective biasing of the substrate region to provide localized attraction of dopant ions. The antennas can be in many different shapes to achieve the desired graded dopant distribution across the substrate or within the bulk of the substrate. In some embodiments, each antenna can have multiple elements that are biased differently both in voltage and in time sequences to provide varying ion dose and energy and species. Some antenna elements can be used to retard ions from doping certain regions and thus achieve abruptly doped regions both in dose and depth. The shape of the attracting potential on the front surface, facing the plasma dopant, can be manipulated to offer almost any resulting doping and other species implanted patterns. Such antenna can be in any shape and have other unique features as desired graded doping requires.

Plasma Grid Implantation (PGI) technology is another broad beam implant technique which extracts multiple beams from plasma through multiple openings in grids that accelerate the ions to a substrate. Plasma grid implantation is described, for example, in U.S. patent application Ser. No. 12/821,053, filed Jun. 22, 2010, entitled “Ion Implant System Having Grid Assembly,” commonly assigned, the entirety of which is hereby incorporated by reference. Any of the above disclosed methods or combination of the above methods can be combined with the plasma grid implantation (PGI) to achieve graded doping or implantation.

The openings in the grid can also be used to shape the pattern of ions implanted into the surface of the wafer. The existence of multiple beamlets emanating from the multiple opening grid can be optically manipulated to the desired shape. These can be in the shape of lines, spots or other unique shapes. Multiple element or grids can be used to further shape the beamlets to the desired species distribution and size. Ion optical simulation has shown for the desired ionized current sizes as small of few microns or as large of few centimeters can be achieved with multiple ion optical elements. The distributions within each beamlets will be dictated by the space charge which is describe by Child Langmuir law and is dependent on the applied Voltage and Current,

$$P ∝ \frac{{V}^{3 / 2}}{{I}^{2}}$$

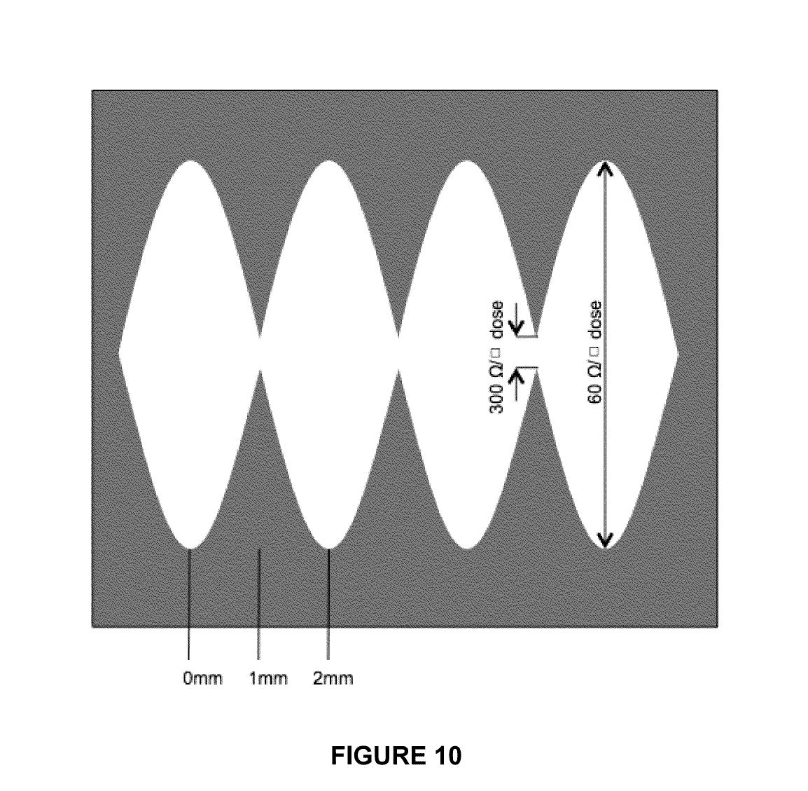

If the wafer is passing through an broad ion beam, a shadow mask can be utilized to create the graded doping and graded sheet resistance. An example of a shadow mask that would result in the graded doping illustrated in FIG. 7 is shown in FIG. 10. The broad ion beam would cover the entire mask while the wafer passes vertically underneath. The highest accumulated doses would occur at the largest parts of the mask openings, while the minimum doping would occur at the narrowest part of the opening.

Such physical phenomena can be used to advantage by adjusting the shape, size and distance of the multiple grids opening and substrate positioning. In some embodiments, a combination of antenna(s) underneath the substrate and the grid manipulation of the ion beam optics can be used to form the graded emitter(s). In some embodiments, a shadow mask can be used to form the graded emitter(s) by varying the height of the shadow mask from the surface of the wafer.

Following implantation of the dopants, the substrate is annealed and the dopants are activated. The subsequent annealing and dopant activation methods can also be used to further introduce shaping of the graded selectivity introducing dopant and other species. There are many methods that can be used for the annealing and dopant activation including, for example, blanket uniform heating of the whole substrate in annealing furnaces and ovens. In some embodiments, localized heating of the top surface layers can also or alternatively be used. In some embodiments, rapid thermal annealing may be used. In rapid thermal annealing, a bank of high intensity lamps are used to heat the very top surface to a very high temperature for a very rapid time. The lamps can be formed into a unique shape to selectively heat up the surface and thus achieve the graded doping both laterally and in the bulk of the substrate.

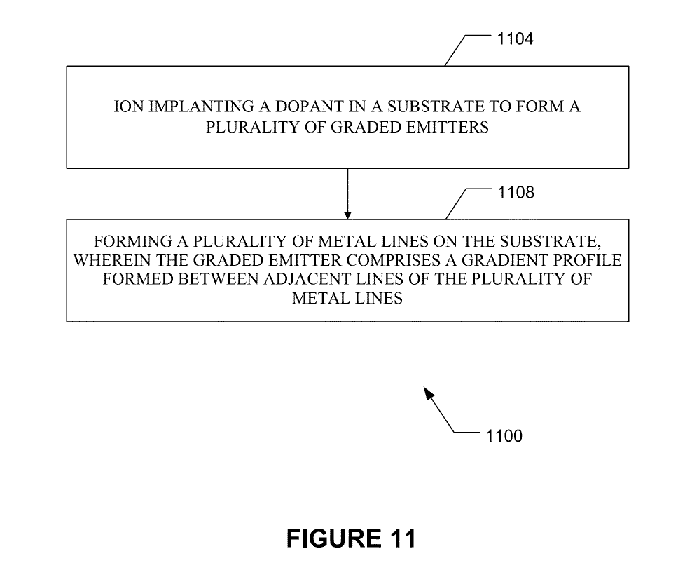

FIG. 11 illustrates another method of making a photovoltaic cell having graded doping regions, such as graded emitters, according to some embodiments of the invention. As shown in FIG. 11, the method 1100 includes ion implanting a dopant in a substrate to form a plurality of graded doping regions (graded emitters) (block 1104), and forming a plurality of metal lines on the substrate, wherein the graded doping region (graded emitter) comprises a gradient profile formed between adjacent lines of the plurality of metal lines (block 1108).

It will be appreciated that the graded doping region may be used to allow for wider spacing of the fingers for a given resistive power loss target, reducing shadowing and silver paste consumption.

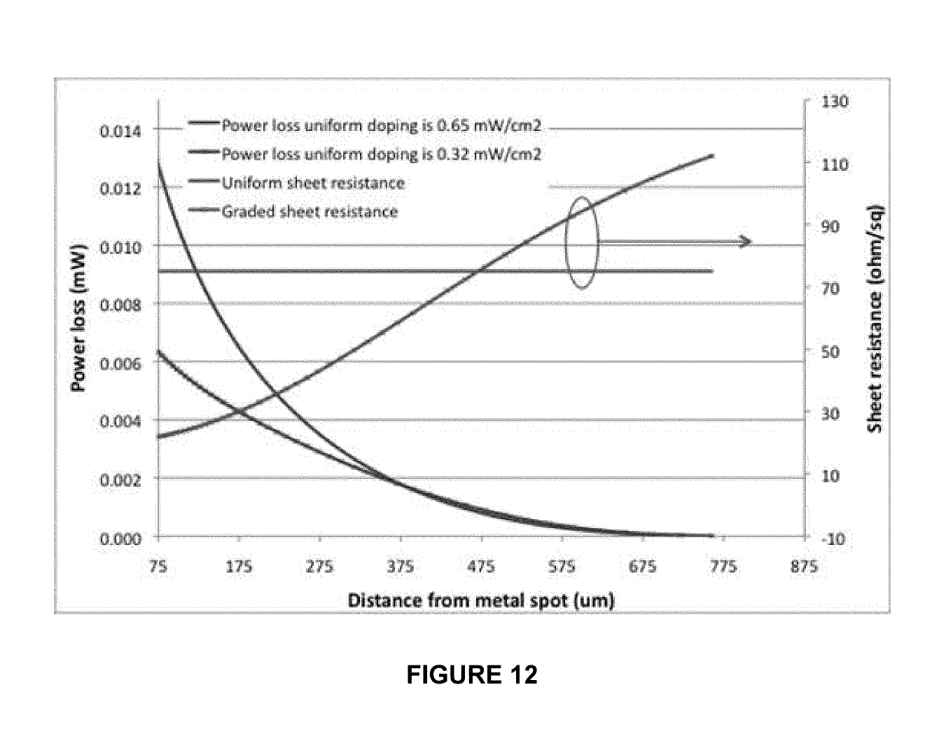

For a circular point contact, the current crowding is even more severe. As the current is collected radially, the current density near the circular metal contact becomes very high, exacerbating the I²R power loss, as shown in FIG. 12. A radially graded doping provides improvement for circular point contacts, as shown in FIG. 12. As shown in FIG. 12, both emitters have a similar total recombination losses, but the graded emitter has half the I²R power loss than the uniform emitter.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. A photovoltaic cell comprising:
a substrate comprising a graded doping region; and
a plurality of metal contacts in contact with at least a portion of the graded doping region.

2. The photovoltaic cell of claim 1, wherein the substrate comprises silicon.

3. The photovoltaic cell of claim 1, wherein the graded doping region comprises a graded emitter.

4. The photovoltaic cell of claim 1, wherein the graded doping region comprises a gradient of dopant in the substrate.

5. The photovoltaic cell of claim 1, further comprising a plurality of busbars in contact with the plurality of metal contacts.

6. The photovoltaic cell of claim 1, wherein the graded doping region comprises a gradual change in sheet resistance over the distance between two of the adjacent plurality of metal contacts.

7. The photovoltaic cell of claim 1, wherein an amount of dopant of the graded doping region is higher at a region of the substrate that experiences current crowding.

8. The photovoltaic cell of claim 1, wherein an amount of dopant of the graded doping region is selected so that there is a gradual change in sheet resistance from one of the plurality of the metal contacts to an adjacent one of the plurality of the metal contacts.

9. The photovoltaic cell of claim 1, wherein a dopant profile of the graded doping region is selected so that a sheet resistance of the substrate near each of the plurality of metal contacts is lower than a sheet resistance of the substrate at a midpoint between each of the plurality of metal contacts.

10. The photovoltaic cell of claim 1, wherein the graded doping region comprises a gradient and a plateau of sheet resistance.

11. A method of making a photovoltaic cell comprising:
forming a graded doping region in a substrate; and
forming a plurality of metal contacts over the substrate.

12. The method of claim 11, wherein forming the graded doping region comprises doping the substrate.

13. The method of claim 12, wherein the doping comprises ion implantation.

14. The method of claim 12, wherein the doping comprises plasma immersion doping.

15. The method of claim 12, wherein the doping comprises plasma grid implantation.

16. The method of claim 12, wherein the doping comprises:
ion implanting a dopant in a gradient profile in a substrate; and
activating the dopant.

17. The method of claim 13, wherein the dopant is ion implanted in a gradient profile between the metal contacts.

18. The method of claim 17, wherein the gradient profile is configured to provide a low sheet resistance near the metal lines and a high sheet resistance between the metal lines.

19. A method of making a photovoltaic cell comprising:
ion implanting a dopant in a substrate to form a plurality of graded doping regions;
forming a plurality of metal lines on the substrate,
wherein the graded doping region comprises a gradient profile formed between adjacent lines of the plurality of metal lines.

20. The method of claim 19, wherein the implanting comprises ion implantation.

21. The method of claim 19, wherein the implanting comprises plasma immersion doping.

22. The method of claim 19, wherein the implanting comprises plasma grid implantation.
